(19) United States
(12) Patent Application Publication
(10) Pub. No.: US 2013/0193984 A1
(43) Pub. Date: Aug. 1, 2013

(54) TEST APPARATUSES FOR MEASURING ELECTROMAGNETIC INTERFERENCE OF IMAGE SENSOR INTEGRATED CIRCUIT DEVICES

(71) Applicants: Se-il KIM, Seoul (KR); Seung-Bae LEE, Yongin-si (KR); Jung-Man LIM, Osan-si (KR); Sung-Chul KIM, Yongin-si (KR); Kyung-Won PARK, Yongin-si (KR); Hyun-Jung PARK, Yongin-si (KR)

(72) Inventors: Se-il KIM, Seoul (KR); Seung-Bae LEE, Yongin-si (KR); Jung-Man LIM, Osan-si (KR); Sung-Chul KIM, Yongin-si (KR); Kyung-Won PARK, Yongin-si (KR); Hyun-Jung PARK, Yongin-si (KR)

(73) Assignee: SAMSUNG ELECTRONICS CO., LTD., Suwon-si (KR)

(21) Appl. No.: 13/610,984

(22) Filed: Sep. 12, 2012

(30) Foreign Application Priority Data
Jan. 30, 2012 (KR) 10-2012-0009157

(51) Int. Cl. G01R 29/26

(52) U.S. Cl. 324/613

(57) ABSTRACT

A test apparatus for measuring electromagnetic interference (EMI) of an image sensor integrated circuit (IC) device may include an EMI test jig configured to drive a mounted image sensor IC device on one or more test conditions; an electromagnetic (EM) shielding box configured to shield external EM waves from other directions except an upper direction, the EM shielding box accepting the EMI test jig; an EM emission sensing probe configured to sense EM emissions from the image sensor IC device, the EM emission sensing probe being separated from and adjacent to the image sensor IC device in the upper direction when sensing EM emissions; and a spectrum analyzer configured to connect to the EM emission sensing probe, the spectrum analyzer configured to evaluate the EM emissions from the image sensor IC device.

### CROSS-REFERENCE TO RELATED APPLICATION(S)

This application claims priority from Korean Patent Application No. 2012-0009157, filed on Jan. 30, 2012, in the Korean Intellectual Property Office (KIPO), the entire contents of which are incorporated herein by reference.

### BACKGROUND

1. Technical Field

Exemplary embodiments may relate to image sensors. Example embodiments also may relate to test apparatuses for measuring electromagnetic interference (EMI) in image sensor integrated circuit (IC) devices.

2. Discussion of the Related Art

As mobile phone sets such as smart phones are highly integrated and operating speed of circuit modules or ICs become faster, the EMI between the circuit modules or ICs arise many problems.

Since the EMI having magnitude greater than a reference magnitude may influence other sets or systems, the EMI is regulated to have magnitude less than the reference magnitude. In addition, in mobile application such as smart phones, the EMI is induced in antenna and thereby may influence communication integrity.

Particularly, image sensors are located adjacently to the antenna in the mobile application such as smart phones, the image sensors may serve as a source of EMI.

The EMI from the image sensors is radiated into air or is propagated through conduction path such as printed circuit board (PCB), and thus may degrade reception sensitivity or may badly affect other modules or other ICs.

Therefore, the mobile set makers determines pass/fail of the IC based on measuring how much camera modules including the image sensors influence the reception sensitivity of the IC.

### SUMMARY

Some example embodiments may provide test apparatuses capable of independently measuring EMI radiated from image sensor IC devices.

Some example embodiments may provide test apparatuses capable of independently measuring EMI propagated from image sensor IC devices.

In some example embodiments, a test apparatus for measuring electromagnetic interference (EMI) of an image sensor integrated circuit (IC) device may comprise an EMI test jig configured to drive a mounted image sensor IC device on one or more test conditions; an electromagnetic (EM) shielding box configured to shield external EM waves from other directions except an upper direction, the EM shielding box accepting the EMI test jig; an EM emission sensing probe configured to sense EM emissions from the image sensor IC device, the EM emission sensing probe being separated from and adjacent to the image sensor IC device in the upper direction when sensing EM emissions; and/or a spectrum analyzer configured to connect to the EM emission sensing probe, the spectrum analyzer configured to evaluate the EM emissions from the image sensor IC device.

In some example embodiments, the EMI test jig may comprise a circuit board; a shielding conducting layer that covers an upper face of the circuit board except for a central portion of the upper face; a connection socket formed in the central portion of the upper face, the image sensor IC device being configured to mount on the connection socket; and/or a test driving circuit formed in a lower face of the circuit board, the test driving circuit configured to drive the image sensor IC device when the image sensor IC device is mounted on the connection socket.

In some example embodiments, the test driving circuit may be configured to connect to a power supply conducting layer and a ground conducting layer such that the test driving circuit performs independent test operations. The power supply conducting layer and/or the ground conducting layer may be formed in the lower face of the circuit board.

In some example embodiments, the test driving circuit may be configured to drive the image sensor IC device on at least one of the following test conditions: battery powered operation after initialization; full resolution image; maximum analog gain; input/output (I/O) port; serial and parallel interface; fixed output image (color bar or test pattern); maximum frame rate; operating frequency; typical I/O driving strength; power supply voltage; and external clock.

In some example embodiments, the test apparatus may further comprise an EMI grade evaluation device configured to connect to the spectrum analyzer. The EMI grade evaluation device may include an EMI grade evaluation algorithm for determining EMI grade for evaluation frequency bandwidths.

In some example embodiments, the evaluation frequency bandwidths may include harmonic bandwidths of a fundamental clock frequency of the image sensor IC device. The EMI grade evaluation device may evaluate which block of a plurality of blocks of the image sensor IC device serves as an EMI source based on amplitudes of the harmonic bandwidths.

In some example embodiments, the evaluation frequency bandwidths may include mobile radio-frequency (RF) communication frequency bandwidths. The EMI grade evaluation device may be configured to evaluate whether the EMI exists and whether the EMI influences a frequency band of a high frequency block adjacent to the image sensor IC device in a mobile phone set when the image sensor IC device is mounted on the mobile phone set.

In some example embodiments, the evaluation frequency bandwidths may include wideband frequency bandwidths with 20 MHz spans. The EMI grade evaluation device may be configured to evaluate whether the EMI exists in each of the wideband frequency bandwidths.

In some example embodiments, a test apparatus for measuring electromagnetic interference (EMI) of an image sensor integrated circuit (IC) device may comprise an EMI test jig configured to drive a mounted image sensor IC device on one or more test conditions; a connection device connected to a conducting layer provided as a power line of the EMI test jig, the connection device configured to block direct current (DC) and configured to connect externally an EMI that is generated from the image sensor IC device and that is propagated to the conducting layer; and/or a spectrum analyzer configured to measure the EMI propagated to the conducting layer.

In some example embodiments, the EMI test jig may comprises a shielding conducting layer that covers an upper face of a circuit board of the EMI test jig, except a central portion of the upper face; a connection socket formed in the central portion of the upper face and on which the image sensor IC device is mounted; a test driving circuit formed in a lower face of the circuit board, the test driving circuit configured to drive the image sensor IC mounted on the connection socket; and/or the conducting layer formed in the lower face of the circuit board, the conducting layer configured to serve as the power line for providing power supply voltage to the test driving circuit.

In some example embodiments, the test driving circuit may be configured to drive the image sensor IC device on at least one of the following test conditions: battery powered operation after initialization; full resolution image; maximum analog gain; input/output (I/O) port; serial and parallel interface; fixed output image (color bar or test pattern); maximum frame rate; operating frequency; typical I/O driving strength; power supply voltage; and external clock.

In some example embodiments, the test apparatus may further comprise an EMI grade evaluation device configured to connect to the spectrum analyzer. The EMI grade evaluation device may include an EMI grade evaluation algorithm for determining EMI grades for evaluation frequency bandwidths.

In some example embodiments, the evaluation frequency bandwidths may include harmonic bandwidths of a fundamental clock frequency of the image sensor IC device. The EMI grade evaluation device may be configured to evaluate which block of a plurality of blocks of the image sensor IC device serves as an EMI source based on amplitudes of the harmonic bandwidths.

In some example embodiments, the evaluation frequency bandwidths may include mobile radio-frequency (RF) communication frequency bandwidths. The EMI grade evaluation device may be configured to evaluate whether the EMI exists and whether the EMI influences a frequency band of a high frequency block adjacent to the image sensor IC device in a mobile phone set when the image sensor IC device is mounted on the mobile phone set.

In some example embodiments, the evaluation frequency bandwidths may include wideband frequency bandwidths with 20 MHz spans. The EMI grade evaluation device may be configured to evaluate whether the EMI exists in each of the wideband frequency bandwidths.

In some example embodiments, a test apparatus for measuring electromagnetic interference (EMI) of an image sensor integrated circuit (IC) device may comprise an EMI test jig configured to drive a mounted image sensor IC device on one or more test conditions, the EMI test jig including a connection socket and a shielding conducting layer on a first side of a circuit board, and a test driving circuit, a power supply conducting layer, and a ground conducting layer on a second side of the circuit board; and/or a spectrum analyzer configured to evaluate results from the test driving circuit. The test driving circuit may be connected to the power supply conducting layer and the ground conducting layer.

In some example embodiments, the test apparatus may further comprise an EMI grade evaluation device connected to the spectrum analyzer. The EMI grade evaluation device may include a grade evaluation algorithm for determining EMI grades for evaluation frequency bandwidths.

In some example embodiments, the evaluation frequency bandwidths may include harmonic bandwidths of a fundamental clock frequency of the image sensor IC device. The EMI grade evaluation device may be configured to evaluate which block of a plurality of blocks of the image sensor IC device serves as an EMI source based on amplitudes of the harmonic bandwidths.

In some example embodiments, the evaluation frequency bandwidths may include mobile radio-frequency (RF) communication frequency bandwidths. The EMI grade evaluation device may be configured to evaluate whether the EMI exists and whether the EMI influences a frequency band of a high frequency block adjacent to the image sensor IC device in a mobile phone set when the image sensor IC device is mounted on the mobile phone set.

In some example embodiments, the evaluation frequency bandwidths may include wideband frequency bandwidths with 20 MHz spans. The EMI grade evaluation device may be configured to evaluate whether the EMI exists in each of the wideband frequency bandwidths.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1 is a block diagram illustrating a test apparatus for measuring electromagnetic interference (EMI) of an image sensor integrated circuit (IC) device according to some example embodiments.

FIG. 2 is a table illustrating examples of frequency bandwidths that may be tested in the test apparatus of FIG. 1.

FIG. 3 illustrates test conditions of the image sensor IC device in FIG. 1.

FIG. 4 is a table illustrating reference amplitudes in each frequency bandwidth for class evaluation.

FIG. 5 is a graph illustrating EM spectrum measured by the test apparatus in GSM 850 bandwidth.

FIG. 6 is a flow chart for explaining EMI grade evaluation algorithm executed in the EMI grade evaluation device.

FIG. 7 is a block diagram illustrating a test apparatus for measuring EMI of an image sensor IC device according to some example embodiments.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

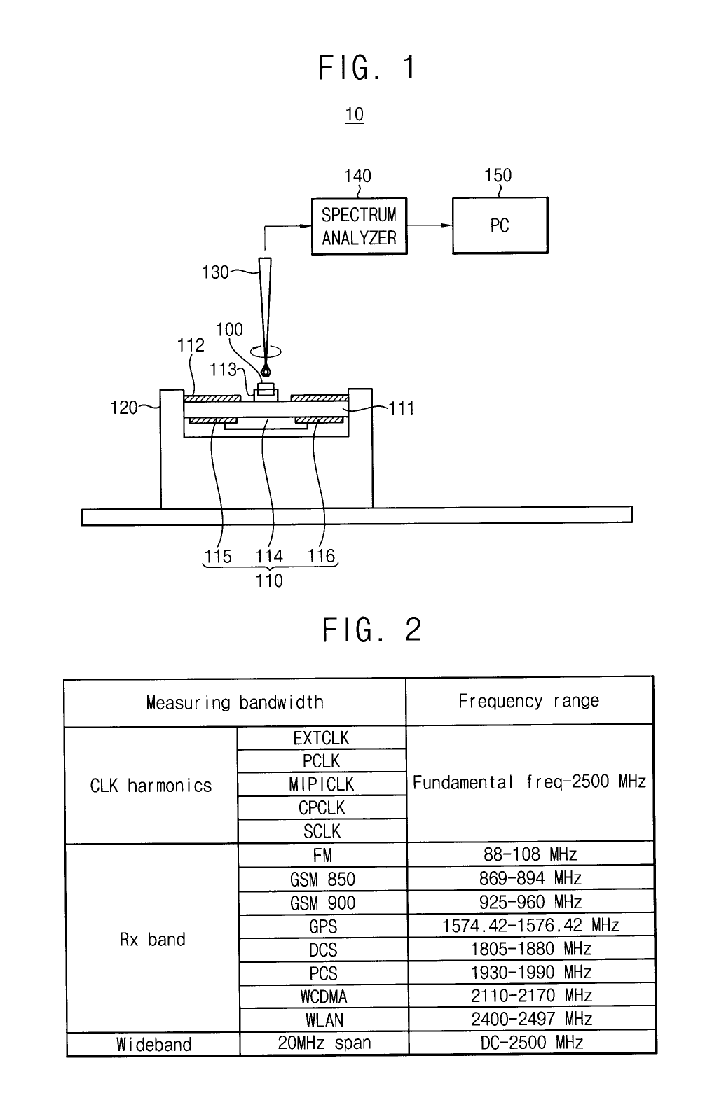

FIG. 1 is a block diagram illustrating a test apparatus for measuring electromagnetic interference (EMI) of an image sensor integrated circuit (IC) device according to some example embodiments.

Referring to FIG. 1, a test apparatus 10 may include an EMI test jig 110, an electromagnetic (EM) shielding box 120, an EM emission sensing probe 130, a spectrum analyzer 140 and an EMI grade evaluation device 150 which is represented as a personal computer (PC).

The EMI test jig 110 drives a mounted image sensor IC device 100 on test condition(s). The EMI test jig 110 includes a circuit board 111, a shielding conducting layer 112 that covers an upper face of the circuit board 111 except a center portion of an upper face of the circuit board 111, and a connection socket 113 on which the image sensor IC device 100 is mounted. The EMI test jig 110 may be formed in the center portion of the upper face and a test driving circuit 114 that is formed in a lower face of the circuit board 111 and which drives the image sensor IC device 100. The test driving circuit 114 is connected to a power supply conducting pattern layer 115 and a ground conducting pattern layer 116, and the test driving circuit 114 is provided with power supply voltage.

The test driving circuit 114 may include a central processing unit (CPU), synchronous dynamic random-access memory (SDRAM), read-only memory (ROM), and/or a flash memory. The test driving circuit 114 also may include a serial input/output (I/O) interface, a clock frequency generator, and/or an AC-DC converter. The test driving circuit 114 drives the image sensor IC device 100 mounted on the connection socket 113 according to a test program stored in the flash memory device. The EM radiation generated from the test driving circuit 114 is shielded by the power supply conducting pattern layer 115 and the ground conducting pattern layer 116.

An EM emission sensing probe 130 is installed on a supporting stand whose angle and height may be adjusted, and a tip of the EM emission sensing probe 130 is separated from the image sensor IC device 100 by about 5 cm in an upper direction perpendicular to the upper face of the image sensor IC device 100. The EM emission sensing probe 130 may be rotated. The EM emission from the image sensor IC device 100 is measured three times at 0, 45 and 90 degrees with respect to z-axis which is identical to the upper direction.

The EM emission sensing probe 130 is connected to the spectrum analyzer 140 via a cable. The sensed EM emission is displayed in waveform image in the spectrum analyzer 140. The spectrum analyzer 140 is connected to the EMI grade evaluation device 150 such as personal computer. The sensed EM emission is provided to the EMI grade evaluation device 150 and is stored in a storage medium such as hard disk.

The EMI grade evaluation device 150 executes an EMI grade evaluation algorithm. The EMI grade algorithm may be implemented with software and may be installed in the EMI grade evaluation device 150.

FIG. 2 is a table illustrating examples of frequency bandwidths that may be tested in the test apparatus of FIG. 1.

Referring to FIG. 2, the test apparatus 10 of FIG. 1 measures EMI of the image sensor IC device 100 when the image sensor IC device 100 operates on clock harmonics CLK harmonics ranging from fundamental frequencies of clock frequencies EXTCLK, PCLK, MIPICLK, CPCLK and SCLK to 2500 MHz. The clock harmonics CLK harmonics are measured for determining which block of a plurality of blocks of the image sensor IC device 100 serves as EMI source.

In addition, the test apparatus 10 of FIG. 1 measures EMI of the image sensor IC device 100 when the image sensor IC device 100 operates on receiver (Rx) bandwidths including frequency modulation (FM) broadcasting bandwidth ranging from 88 MHz to 108 MHz, global system for mobile communication (GSM) 850 communication bandwidth ranging from 869 MHz to 894 MHz, GSM 900 communication bandwidth ranging from 925 MHz to 960 MHz, global positioning system (GPS) satellite position data communication bandwidth ranging from 1574.42 MHz to 1576.42 MHz, data communication service (DCS) communication bandwidth ranging from 1805 MHz to 1880 MHz, personal communication service (PCS) communication bandwidth ranging from 1930 MHz to 1990 MHz, wideband code division multiple access (WCDMA) communication bandwidth ranging from 2110 MHz to 2170 MHz and wireless local area network (WLAN) communication bandwidth ranging from 2400 MHz to 2497 MHz. The EMI is measured at each of the Rx bandwidths, and the set manufactures designs the mobile set considering the measured EMI based on the intended Rx bandwidth.

In addition, the test apparatus of FIG. 1 measures EMI of the image sensor IC device 100 when the image sensor IC device 100 operates on wideband frequency bandwidth for determining whether broadband noise exist. In wideband, the EMI of the image sensor IC device 100 is measured at a 20 MHz span.

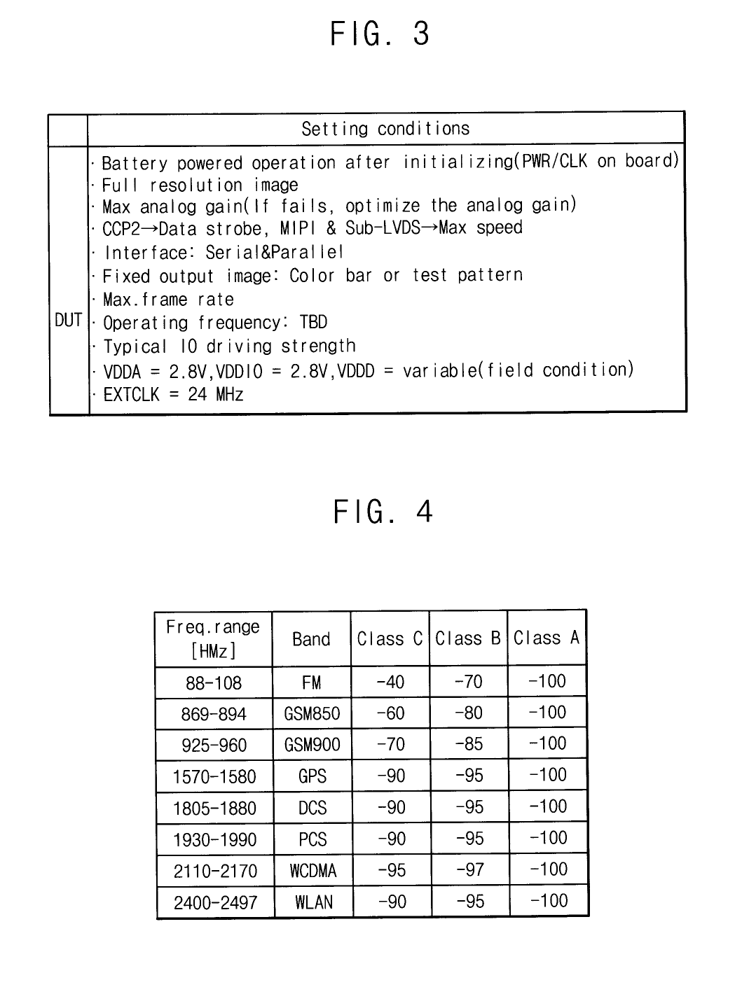

FIG. 3 illustrates test conditions of the image sensor IC device in FIG. 1.

Referring to FIG. 3, the test driving circuit 114 drives the image sensor IC device 100 on at least one of the following test conditions:

battery powered operation after initialization (PWR/CLK on board);

full resolution image;

maximum analog gain (If fails, optimize the analog gain);

input/output (I/O) port (CCP2: data strobe;, MIPI and Sub-LVDS; maximum speed); serial and parallel interface;

fixed output image (color bar or test pattern);

maximum frame rate;

operating frequency: to be determined (TBD);

typical I/O driving strength;

power supply voltage (VDDA=2.8V, VDDIO=2.8V, VDDD=variable); and external clock (24 MHz),

where CCP2 denotes compact camera port 2, MIPI denotes mobile industry processor interface, LVDS denotes low-voltage differential signaling, and DUT demotes device under test.

The EMI emission from the image sensor IC device 100 is measured when the image sensor IC device 100 is driven on at least one of the above test conditions.

In some example embodiments, the EMI is evaluated as a third class (class C) when the amplitude of the EMI is equal to or greater than −40 dBm, the EMI is evaluated as a second class (class B) when the amplitude of the EMI is in a range from −40 dBm to −70 dBm, and the EMI is evaluated as a first class (class A) when the amplitude of the EMI is less than −70 dBm.

FIG. 4 is a table illustrating reference amplitudes in each frequency bandwidth for class evaluation.

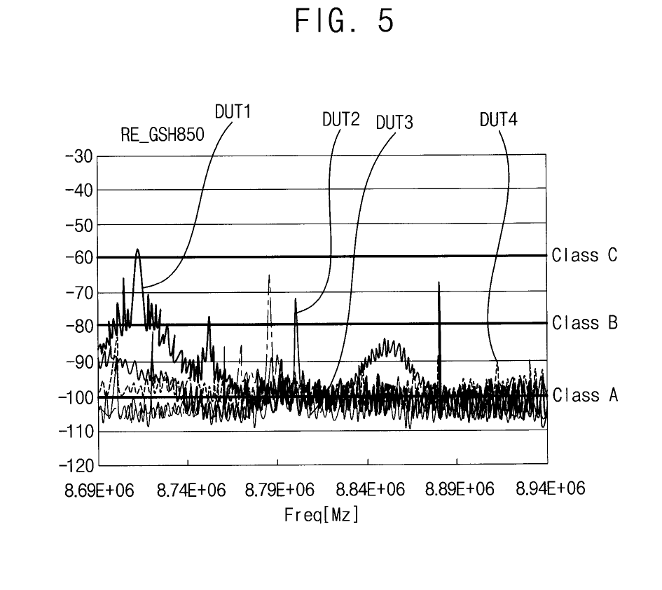

FIG. 5 is a graph illustrating EM spectrum measured by the test apparatus in GSM 850 bandwidth.

Referring to FIGS, 4 and 5, DUT1 is evaluated as class C in 870 MHz bandwidth and is evaluated as class A in other bandwidths. DUT2 is evaluated as class B in 884 MHz and 889 MHz bandwidths. DUT3 and DUT4 are evaluated as class A in overall bandwidths.

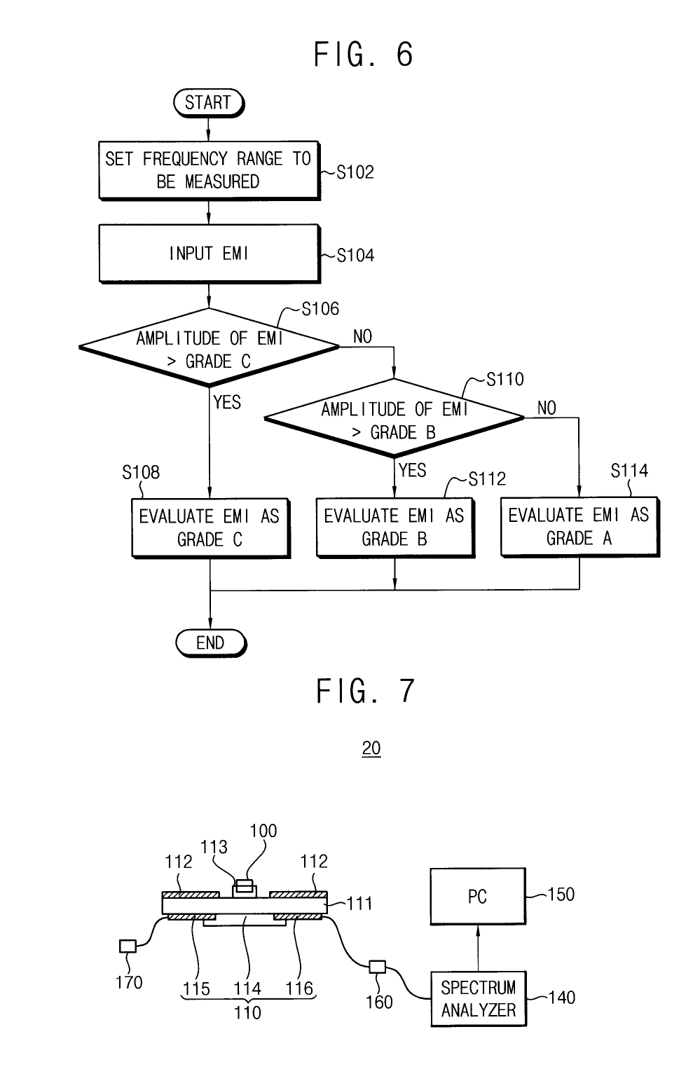

FIG. 6 is a flow chart for explaining EMI grade evaluation algorithm executed in the EMI grade evaluation device 150.

Referring to FIGS. 1 and 6, the EMI grade evaluation device 150 sets a frequency range to be measured (S102), the EMI is input (S 104) and the EMI grade evaluation device 150 compares the amplitude of the EMI provided through the spectrum analyzer 140 with the reference amplitude in the class C (S106). The EMI is evaluated as class C (S108) when the amplitude of the EMI is greater than the reference amplitude in the class C (YES in S106). When the amplitude of the EMI is not greater than the reference amplitude in the class C in step S106 (NO in S106), the EMI grade evaluation device 150 compares the amplitude of the EMI provided through the spectrum analyzer 140 with the reference amplitude in the class B (S110). The EMI is evaluated as class B (S112) when the amplitude of the EMI is greater than the reference amplitude in the class B (YES in S110). When the amplitude of the EMI is not greater than the reference amplitude in the class B (NO in S110), the EMI is evaluated as class A (S114).

FIG. 7 is a block diagram illustrating a test apparatus for measuring EMI of an image sensor IC device according to some example embodiments.

The test apparatus 20 of FIG. 7 differs from the test apparatus of FIG. 1 in that the test apparatus 10 of FIG. 1 measures radiated EMI of the image sensor IC device and the test apparatus 20 of FIG. 7 measures propagated EMI of the image sensor IC device.

Referring to FIG. 7, the test apparatus 20 may include an EMI test jig 110, an EM emission sensing probe 130, a spectrum analyzer 140 and an EMI grade evaluation device 150 which is represented as a personal computer.

The EMI test jig 110 drives a mounted image sensor IC device 100 on test condition(s). The EMI test jig 110 includes a circuit board 111, a shielding conducting layer 112 that covers an upper face of the circuit board 111 except a center portion of an upper face of the circuit board 111, a connection socket 113 on which the image sensor IC device 100 and which is mounted and is formed in the center portion of the upper face and a test driving circuit 114 that is formed in a lower face of the circuit board 111 and which drives the image sensor IC device 100. The test driving circuit 114 is connected to a power supply conducting pattern layer 115 and a ground conducting pattern layer 116, and the test driving circuit 114 is provided with power supply voltage. Connection devices 160 and 170 are connected to the power supply conducting pattern layer 115 and the ground conducting pattern layer 116. The connection device 160 is connected to the spectrum analyzer 140. The connection devices 160 and 170 may include direct current (DC) blocking filter or a high pass filter that blocks DC components but passes propagated EMI with alternating current (AC) components. The connection device 160 is connected to the spectrum analyzer 140 via a cable and receives the propagated EMI.

The spectrum analyzer 140 is connected to the EMI grade evaluation device 150 such as personal computer. The propagated EMI is provided to the EMI grade evaluation device 150 and is stored in a storage medium such as hard disk.

The EMI grade evaluation device 150 executes an EMI grade evaluation algorithm. The EMI grade evaluation device 150 evaluates the propagated EMI in each frequency bandwidth as described with reference to FIGS. 1 to 6.

Many of the described features may be substituted, altered or omitted without departing from the scope of the inventive concept. It should be understood that functions and/or operation of the blocks in some example embodiments may be implemented in hardware, firmware, software or any combination thereof. In addition, it should be understood that functions and/or operation of the blocks in some example embodiments may be implemented in software that may be running on general purpose processor or a special purpose processor.

While example embodiments have been particularly shown and described, it will be understood by those of ordinary skill in the art that various changes in form and details may be made therein without departing from the spirit and scope of the present invention as defined by the following claims.

What is claimed is:

1. A test apparatus for measuring electromagnetic interference (EMI) of an image sensor integrated circuit (IC) device, the test apparatus comprising:
an EMI test jig configured to drive a mounted image sensor IC device on one or more test conditions;
an electromagnetic (EM) shielding box configured to shield external EM waves from other directions except an upper direction, the EM shielding box accepting the EMI test jig;
an EM emission sensing probe configured to sense EM emissions from the image sensor IC device, the EM emission sensing probe being separated from and adjacent to the image sensor IC device in the upper direction when sensing EM emissions; and
a spectrum analyzer configured to connect to the EM emission sensing probe, the spectrum analyzer configured to evaluate the EM emissions from the image sensor IC device.

2. The test apparatus of claim 1, wherein the EMI test jig comprises:
a circuit board;
a shielding conducting layer that covers an upper face of the circuit board except for a central portion of the upper face;
a connection socket formed in the central portion of the upper face, the image sensor IC device being configured to mount on the connection socket; and
a test driving circuit formed in a lower face of the circuit board, the test driving circuit configured to drive the image sensor IC device when the image sensor IC device is mounted on the connection socket.

3. The test apparatus of claim 2, wherein the test driving circuit is configured to connect to a power supply conducting layer and a ground conducting layer such that the test driving circuit performs independent test operations, and
wherein the power supply conducting layer and the ground conducting layer are formed in the lower face of the circuit board.

4. The test apparatus of claim 2, wherein the test driving circuit is configured to drive the image sensor IC device on at least one of the following test conditions:
battery powered operation after initialization;
full resolution image;
maximum analog gain;
input/output (I/O) port;
serial and parallel interface;
fixed output image (color bar or test pattern);
maximum frame rate;
operating frequency;
typical I/O driving strength;
power supply voltage; and
external clock.

5. The test apparatus of claim 2, further comprising:
an EMI grade evaluation device configured to connect to the spectrum analyzer;
wherein the EMI grade evaluation device includes an EMI grade evaluation algorithm for determining EMI grade for evaluation frequency bandwidths.

6. The test apparatus of claim 5, wherein the evaluation frequency bandwidths include harmonic bandwidths of a fundamental clock frequency of the image sensor IC device, and
wherein the EMI grade evaluation device evaluates which block of a plurality of blocks of the image sensor IC device serves as an EMI source based on amplitudes of the harmonic bandwidths.

7. The test apparatus of claim 5, wherein the evaluation frequency bandwidths include mobile radio-frequency (RF) communication frequency bandwidths, and
wherein the EMI grade evaluation device is configured to evaluate whether the EMI exists and whether the EMI influences a frequency band of a high frequency block adjacent to the image sensor IC device in a mobile phone set when the image sensor IC device is mounted on the mobile phone set.

8. The test apparatus of claim 5, wherein the evaluation frequency bandwidths include wideband frequency bandwidths with 20 MHz spans, and
wherein the EMI grade evaluation device is configured to evaluate whether the EMI exists in each of the wideband frequency bandwidths.

9. A test apparatus for measuring electromagnetic interference (EMI) of an image sensor integrated circuit (IC) device, the test apparatus comprising:
an EMI test jig configured to drive a mounted image sensor IC device on one or more test conditions;
a connection device connected to a conducting layer provided as a power line of the EMI test jig, the connection device configured to block direct current (DC) and configured to connect externally an EMI that is generated from the image sensor IC device and that is propagated to the conducting layer; and
a spectrum analyzer configured to measure the EMI propagated to the conducting layer.

10. The test apparatus of claim 9, wherein the EMI test jig comprises:
a shielding conducting layer that covers an upper face of a circuit board of the EMI test jig, except a central portion of the upper face;
a connection socket formed in the central portion of the upper face and on which the image sensor IC device is mounted;
a test driving circuit formed in a lower face of the circuit board, the test driving circuit configured to drive the image sensor IC mounted on the connection socket; and
the conducting layer formed in the lower face of the circuit board, the conducting layer configured to serve as the power line for providing power supply voltage to the test driving circuit.

11. The test apparatus of claim 10, wherein the test driving circuit is configured to drive the image sensor IC device on at least one of the following test conditions:
battery powered operation after initialization;
full resolution image;
maximum analog gain;
input/output (I/O) port;
serial and parallel interface;
fixed output image (color bar or test pattern);
maximum frame rate;
operating frequency;
typical I/O driving strength;
power supply voltage; and
external clock.

12. The test apparatus of claim 9, further comprising:
an EMI grade evaluation device configured to connect to the spectrum analyzer;
wherein the EMI grade evaluation device includes an EMI grade evaluation algorithm for determining EMI grades for evaluation frequency bandwidths.

13. The test apparatus of claim 12, wherein the evaluation frequency bandwidths include harmonic bandwidths of a fundamental clock frequency of the image sensor IC device, and
wherein the EMI grade evaluation device is configured to evaluate which block of a plurality of blocks of the image sensor IC device serves as an EMI source based on amplitudes of the harmonic bandwidths.

14. The test apparatus of claim 12, wherein the evaluation frequency bandwidths include mobile radio-frequency (RF) communication frequency bandwidths, and
wherein the EMI grade evaluation device is configured to evaluate whether the EMI exists and whether the EMI influences a frequency band of a high frequency block adjacent to the image sensor IC device in a mobile phone set when the image sensor IC device is mounted on the mobile phone set.

15. The test apparatus of claim 12, wherein the evaluation frequency bandwidths include wideband frequency bandwidths with 20 MHz spans, and
wherein the EMI grade evaluation device is configured to evaluate whether the EMI exists in each of the wideband frequency bandwidths.

16. A test apparatus for measuring electromagnetic interference (EMI) of an image sensor integrated circuit (IC) device, the test apparatus comprising:
an EMI test jig configured to drive a mounted image sensor IC device on one or more test conditions, the EMI test jig including a connection socket and a shielding conducting layer on a first side of a circuit board, and a test driving circuit, a power supply conducting layer, and a ground conducting layer on a second side of the circuit board; and
a spectrum analyzer configured to evaluate results from the test driving circuit;
wherein the test driving circuit is connected to the power supply conducting layer and the ground conducting layer.

17. The test apparatus of claim 16, further comprising:
an EMI grade evaluation device connected to the spectrum analyzer;
wherein the EMI grade evaluation device includes a grade evaluation algorithm for determining EMI grades for evaluation frequency bandwidths.

18. The test apparatus of claim 17, wherein the evaluation frequency bandwidths include harmonic bandwidths of a fundamental clock frequency of the image sensor IC device, and
wherein the EMI grade evaluation device is configured to evaluate which block of a plurality of blocks of the image sensor IC device serves as an EMI source based on amplitudes of the harmonic bandwidths.

19. The test apparatus of claim 17, wherein the evaluation frequency bandwidths include mobile radio-frequency (RF) communication frequency bandwidths, and
wherein the EMI grade evaluation device is configured to evaluate whether the EMI exists and whether the EMI influences a frequency band of a high frequency block adjacent to the image sensor IC device in a mobile phone set when the image sensor IC device is mounted on the mobile phone set.

20. The test apparatus of claim 17, wherein the evaluation frequency bandwidths include wideband frequency bandwidths with 20 MHz spans, and
wherein the EMI grade evaluation device is configured to evaluate whether the EMI exists in each of the wideband frequency bandwidths.
